(19) United States
(12) Patent Application Publication
(10) Pub. No.: US 2014/0110759 A1
(43) Pub. Date: Apr. 24, 2014

(54) SEMICONDUCTOR DEVICE

(71) Applicant: PANASONIC CORPORATION, Osaka (JP)

(72) Inventors: Tomohiro MURATA, Osaka (JP); Daisuke SHIBATA, Kyoto (JP); Tetsuzo UEDA, Osaka (JP)

(73) Assignee: PANASONIC CORPORATION, Osaka (JP)

(21) Appl. No.: 14/140,325

(22) Filed: Dec. 24, 2013

Related U.S. Application Data
(63) Continuation of application No. PCT/JP2012/003732, filed on Jun. 7, 2012.

(30) Foreign Application Priority Data
Jul. 1, 2011 (JP) 2011-147646

(51) Int. Cl. H01L 29/778; H01L 29/872

(52) U.S. Cl. CPC H01L 29/7783; H01L 29/872
USPC 257/194

(57) ABSTRACT

A semiconductor device includes a first hetero-junction body in which a first channel layer and a first barrier layer are bonded together; a second hetero-junction body in which a second channel layer formed on the first hetero-junction body and a second barrier layer are bonded together; a gate electrode in Schottky contact with the second barrier layer; and source and drain electrodes in ohmic contact with the first and second hetero-junction bodies. At least one of the first and second channel layers has such a thickness that an electron concentration in a 2DEG layer formed in the channel layer is not reduced.

### CROSS-REFERENCE TO RELATED APPLICATIONS

This is a continuation of International Application No. PCT/JP2012/003732 filed on Jun. 7, 2012, which claims priority to Japanese Patent Application No. 2011-147646 filed on Jul. 1, 2011. The entire disclosures of these applications are incorporated by reference herein.

### BACKGROUND

The present disclosure relates to, e.g., a semiconductor device applicable to a power device.

In recent years, there is an increasing demand for higher output power and size reduction in power application circuits. Thus, a need for higher output power and size reduction has been also growing in devices to be built in the power application circuits. Consideration has been made to apply group III nitride semiconductors, such as gallium nitride (GaN), aluminum nitride (AlN), or indium nitride (InN), which are mixed crystals each represented by a general formula of (InₓAl₁₋ₓ)_{y}Ga_{1-y}N (where “x” and “y” satisfy 0≦x≦1 and 0≦y≦1). This is because the nitride semiconductor has both of high breakdown voltage characteristics due to a great band gap and a high current density due to 2-dimentional electron gas (hereinafter referred to as “2DEG”) having a high electron concentration at an interface between AlₓGa₁₋ₓN and GaN.

In order to reduce a device size, attempt has been made to improve a current density in a channel. Japanese Unexamined Patent Publication No. 2009-117485 has proposed a Schottky barrier diode (hereinafter referred to as an “SBD”), and International Publication No. 2000/065663 has proposed a hetero-junction field effect transistor (hereinafter referred to as an “HFET”). In Japanese Unexamined Patent Publication No. 2009-117485 and International Publication No. 2000/065663, the SBD and the HFET have a hetero-structure of AlGaN/GaN having a plurality of 2DEG channels (multiple 2DEG channels). In Japanese Unexamined Patent Publication No. 2009-117485, various studies have been, for improvement of a 2DEG concentration in the multiple 2DEG channels, conducted on AlGaN parameters such as an Al composition and a thickness.

### SUMMARY

However, the present inventors have found, as a result of the various studies, a disadvantage that it is difficult to realize a high current density even with the multiple 2DEG channels in the conventional SBD and HFET.

FIG. 14 illustrates results of comparison in current-voltage (I-V) characteristics between a conventional GaN-based SBD having multiple 2DEG channels and a conventional single channel-type SBD having a single 2DEG channel.

Referring to a cross-sectional view of FIG. 14, a triple channel-type SBD is configured such that, e.g., a GaN layer 11, an AlGaN layer 12, a GaN layer 13, an AlGaN layer 14, a GaN layer 15, and an AlGaN layer 16 are epitaxially grown in this order on a substrate 10. A 2DEG channel 20 is formed at each of an interface between the GaN layer 11 and the AlGaN layer 12, an interface between the GaN layer 13 and the AlGaN layer 14, and an interface between the GaN layer 15 and the AlGaN layer 16. A Schottky contact anode electrode 17 is formed on one of side surfaces of the stack of semiconductor layers, whereas an ohmic contact cathode electrode 18 is formed on the other side surface of the stack of semiconductor layers.

A graph of FIG. 14 shows almost no current increase due to the multiple 2DEG channels 20 even though there are three 2DEG channels 20.

Reasons for the foregoing are as follows.

First, FIG. 15 illustrates an energy state at a lower end of a conduction band (Ec) including multiple 2DEG channels in an AlGaN/GaN-based semiconductor. Referring to FIG. 15, a positive polarization charge (+Q, +Q′) generated at a hetero-interface of epitaxially-grown AlGaN/GaN layers induces high-concentration 2DEG. However, since a dipole, i.e., a pair of positive and negative charges, is formed by polarization, the same amount of negative polarization charge (−Q, −Q′) as the amount of positive polarization charge (+Q, +Q′) is generated at an interface of GaN/AlGaN opposite to the interface at which the 2DEG is generated. Such a negative polarization charge (−Q, −Q′) extends a depletion layer at the interface. This increases potential in the 2DEG channel, resulting in lowering of an electron concentration.

For improvement of an electron concentration in a 2DEG channel in a conventional AlGaN/GaN-based device, studies have been conducted on AlGaN parameters such as an Al composition and a thickness. This is because the amount of polarization charge is determined depending on parameters for an AlGaN layer and an increase in positive polarization charge inducing 2DEG results in an increase in electron concentration in the 2DEG channel. However, the experimental results illustrated in FIG. 14 show that the conventional method focusing on the AlGaN layer in the case of multiple 2DEG channels is not satisfactory and that it is necessary to consider the negative polarization charge reducing the electron concentration.

The present disclosure aims to accomplish the foregoing objective and to, in a group III nitride semiconductor device having multiple 2DEG channels, effectively increase a current density and to realize a small high-power semiconductor device.

In order to accomplish the foregoing objective, the semiconductor device of the present disclosure is configured such that a nitride semiconductor layer with a smaller band gap is sandwiched between other nitride semiconductor layers with a greater band gap to form a hetero-junction body and that the thickness of the nitride semiconductor layer with the smaller band gap is optimized (adjusted) to reduce a decrease in electron concentration in a 2DEG channel due to a negative polarization charge generated in the nitride semiconductor layer with the smaller band gap.

Specifically, the semiconductor device of the present disclosure includes a first hetero-junction body in which a first nitride semiconductor layer and a second nitride semiconductor layer having a greater band gap than that of the first nitride semiconductor layer are bonded together; a second hetero-junction body in which a third nitride semiconductor layer formed on the first hetero-junction body and a fourth nitride semiconductor layer having a greater band gap than that of the third nitride semiconductor layer are bonded together; a first electrode in Schottky contact with at least the fourth nitride semiconductor layer; and a second electrode in ohmic contact with the first and second hetero-junction bodies. The first nitride semiconductor layer has such a thickness that an electron concentration in a 2-dimentional electron gas (2DEG) layer formed in the first nitride semiconductor layer is not reduced, or the third nitride semiconductor layer has such a thickness that an electron concentration in a 2-dimentional electron gas (2DEG) layer formed in the third nitride semiconductor layer is not reduced.

According to the semiconductor device of the present disclosure, the first or third nitride semiconductor layer has such a thickness that the electron concentration in the 2DEG layer formed in the first or third nitride semiconductor layer is not reduced. That is, the first or third nitride semiconductor layer has a thickness sufficient not to reduce the electron concentration in the 2DEG layer. Thus, the first or third nitride semiconductor layer having a specific thickness moderates an influence, on the 2DEG layer, of a negative polarization charge generated at an upper surface of the second nitride semiconductor layer. Consequently, a sufficiently high electron concentration in the 2DEG layer can be realized.

In the semiconductor device of the present disclosure, the thickness of the first nitride semiconductor layer or the third nitride semiconductor layer is preferably equal to or greater than 80 nm.

According to such a configuration, it can be ensured that a decrease in electron concentration in the 2DEG layer due to the negative polarization charge is reduced.

In the semiconductor device of the present disclosure, the third nitride semiconductor layer may have, at an interface at which the third nitride semiconductor layer contacts the second nitride semiconductor layer, a first region doped with an n-impurity.

According to such a configuration, since the third nitride semiconductor layer has, at the interface at which the third nitride semiconductor layer contacts the second nitride semiconductor layer, the first region doped with the n-impurity, the electron concentration in the 2DEG layer formed in the first nitride semiconductor layer can be improved.

In this case, the third nitride semiconductor layer may have a second region formed between the first region and the fourth nitride semiconductor layer so as to contact the first region and doped with a p-impurity.

As in the foregoing, when the layer of p-impurity whose total amount is in balance with that of the n-impurity is provided in the second region contacting the first region in the third nitride semiconductor layer, if field intensity increases in a channel direction, a depletion layer at a pn junction is extended to reduce electric field concentration. As a result, a desired high breakdown voltage of the semiconductor device can be ensured.

In the semiconductor device of the present disclosure, the first electrode is preferably a gate electrode, the second electrode preferably includes a source electrode formed in a region extending the first and second hetero-junction bodies on one side of the gate electrode, and a drain electrode formed in a region extending the first and second hetero-junction bodies on the other side of the gate electrode, and the semiconductor device is preferably operated as a field effect transistor.

According to such a configuration, a drain current density in the field effect transistor can be improved.

In this case, the first electrode may be a first gate electrode, a substrate configured to hold the first hetero-junction body may be further provided, the substrate may be provided in a region of the semiconductor device opposite to the first gate electrode, and may be formed with an opening through which part of the first hetero-junction body is exposed, and a second gate electrode contacting at least the part of the first hetero-junction body exposed through the opening may be formed on the substrate.

As in the foregoing, since the gate electrode of the field effect transistor is provided on each of upper and lower sides, controllability of a drain current even in a channel at a deep position can be improved by application of a gate voltage.

In the semiconductor device of the present disclosure, the first electrode is preferably an anode electrode, the second electrode is preferably a cathode electrode, and the semiconductor device is preferably operated as a Schottky barrier diode.

According to such a configuration, a Schottky barrier diode (SBD) having a high current density can be realized.

In this case, the thickness of the third nitride semiconductor layer may be equal to or less than 350 nm.

According to such a configuration, Schottky barrier reduction accompanied by concentration improvement in the 2DEG layer and an increase in leakage current can be reduced.

According to the semiconductor device of the present disclosure, in a semiconductor device made of a group III nitride semiconductor and having multiple 2DEG channels, an effective increase in current density can be realized with size reduction and higher output power.

### BRIEF DESCRIPTION OF THE DRAWINGS

FIG. 1 is a schematic cross-sectional view illustrating a semiconductor device of a first embodiment of the present disclosure.

FIG. 2 is a graph illustrating a relationship between the thickness of a second channel layer and a measured resistance value in the semiconductor device of the present disclosure.

FIG. 3 is a graph illustrating results obtained by calculating, for different Al compositions and thicknesses of each barrier layer and different thicknesses of the second channel layer, a change in electron concentration in an upper-side 2DEG channel of the semiconductor device of the first embodiment of the present disclosure.

FIG. 4 is a schematic cross-sectional view illustrating a semiconductor device of a first variation of the first embodiment of the present disclosure.

FIG. 5 is a schematic cross-sectional view illustrating a semiconductor device of a second variation of the first embodiment of the present disclosure.

FIG. 6 is a graph illustrating a relationship between the thickness of a second channel layer and a measured reverse leakage current in the semiconductor device of the second variation of the first embodiment of the present disclosure.

FIG. 7 is a schematic cross-sectional view illustrating a semiconductor device of a third variation of the first embodiment of the present disclosure.

FIG. 8 is a schematic cross-sectional view illustrating a semiconductor device of another example of the third variation of the first embodiment of the present disclosure.

FIG. 9 is a schematic cross-sectional view illustrating a semiconductor device of a fourth variation of the first embodiment of the present disclosure.

FIG. 10 is a schematic cross-sectional view illustrating a semiconductor device of a fifth variation of the first embodiment of the present disclosure.

FIG. 11 is a schematic cross-sectional view illustrating a semiconductor device of a sixth variation of the first embodiment of the present disclosure.

FIG. 12 is a schematic cross-sectional view illustrating a semiconductor device of a second embodiment of the present disclosure.

FIG. 13 is a graph illustrating results obtained by calculating, for different n-impurity concentration in a first region of a second channel layer, a change in electron concentration in a 2DEG channel of a first channel layer of the semiconductor device of the second embodiment of the present disclosure.

FIG. 14 is a schematic cross-sectional view illustrating a conventional semiconductor device and a graph illustrating one example of measurement of current-voltage characteristics of the conventional semiconductor device.

FIG. 15 is a schematic diagram illustrating a lower end of a conduction band (Ec) including multiple 2-dimensional electron gas (2DEG) channels in an AlGaN/GaN-based semiconductor device.

### DETAILED DESCRIPTION

### First Embodiment

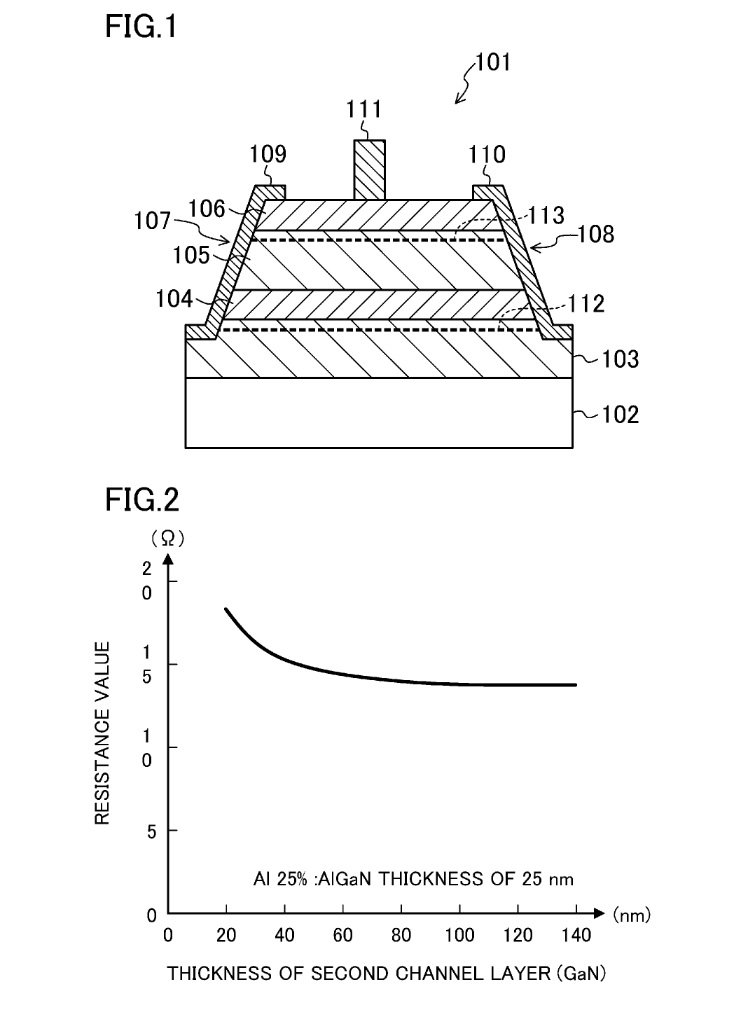

A semiconductor device of a first embodiment of the present disclosure will be described with reference to FIG. 1.

Referring to FIG. 1, a semiconductor device 101 of the first embodiment is a GaN-based field effect transistor.

The field effect transistor is configured such that, e.g., a first channel layer 103 made of GaN, a first barrier layer 104 made of AlGaN, a second channel layer 105 made of GaN, and a second barrier layer 106 made of AlGaN are, by metal organic chemical vapor deposition (MOCVD), epitaxially grown in this order on a substrate 102 made of silicon (Si).

As in the foregoing, a first hetero-junction body is formed of the first channel layer 103 and the first barrier layer 104, and a second hetero-junction body is formed of the second channel layer 105 and the second barrier layer 106.

The substrate 102 for crystal growth is not limited to silicon. For example, silicon carbide (SiC), sapphire (Al₂O₃), or gallium nitride (GaN) may be used. Moreover, a buffer layer configured to reduce a lattice mismatch between the substrate 102 and the first channel layer 103 may be formed between the substrate 102 and the first channel layer 103.

A 2-dimentional electron gas (2DEG) channel 112 is, in the first channel layer 103, formed in the vicinity of an interface between the first channel layer 103 and the first barrier layer 104, and a 2DEG channel 113 is, in the second channel layer 105, formed in the vicinity of an interface between the second channel layer 105 and the second barrier layer 106.

Right after the epitaxial layer is formed, a wafer is in such a state that the epitaxial layer includes active layers of a plurality of semiconductor devices 101 and are smoothly formed on the entirety of a principal surface of the wafer. Subsequently, a recess for formation of an ohmic electrode contacting the 2DEG channels 112, 113 of the channel layers 103, 105 is formed in each semiconductor device 101.

In a step part 107 of the epitaxial layer, a source electrode 109 and a drain electrode 110 are formed so as to be in ohmic contact with the channel layers 103, 105 and the barrier layers 104, 106. For example, a multilayer film of titanium (Ti) and aluminum (Al) can be used as a metal material which can be in ohmic contact with a nitride semiconductor layer.

In a region of the second barrier layer 106 between the source electrode 109 and the drain electrode 110, a gate electrode 111 in Schottky contact with the second barrier layer 106 is formed on the second barrier layer 106. For example, nickel (Ni) or palladium (Pd) can be used as a metal material which can be in Schottky contact with a nitride semiconductor layer.

In the first embodiment, the first channel layer 103 made of GaN is formed below the first barrier layer 104 having a greater band gap than that of the first channel layer 103 and made of AlGaN. Similarly, the second channel layer 105 made of GaN is formed below the second barrier layer 106 having a greater band gap than that of the second channel layer 105 and made of AlGaN.

In this case, the first channel layer 103 has such a thickness that an electron concentration in the 2DEG channel 112 formed in the first channel layer 103 is not reduced. Moreover, the second channel layer 105 has such a thickness that an electron concentration in the 2DEG channel 113 formed in the second channel layer 105 is not reduced.

FIG. 2 is a graph illustrating a relationship between the thickness of the second channel layer made of GaN and a resistance value. A resistance value between the source electrode 109 and the drain electrode 110 is measured by using a plurality of samples formed with different thicknesses of the second channel layer 105.

Referring to FIG. 2, the resistance value for second channel layer 105 can be decreased in such a manner that the thickness of the second channel layer 105 is set at equal to or greater than 80 nm.

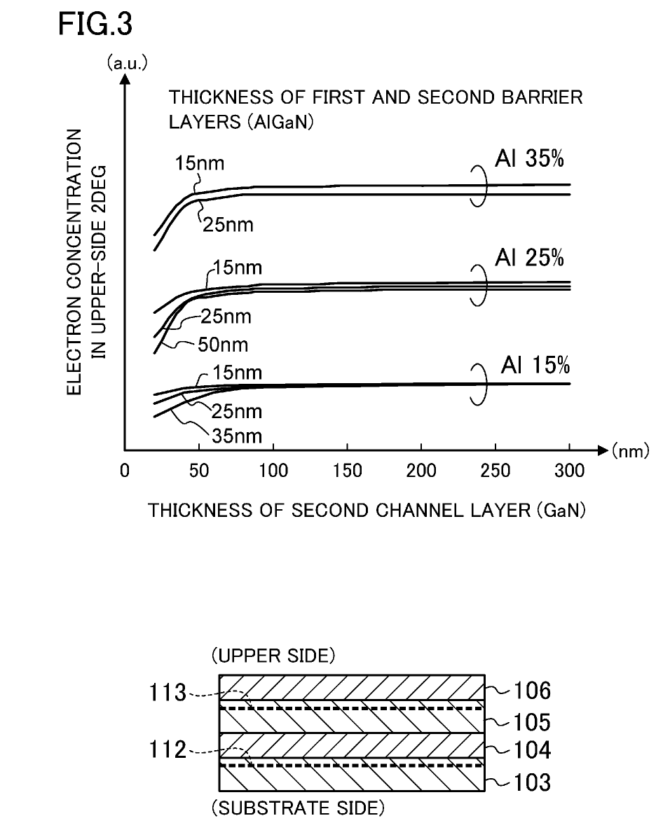

FIG. 3 illustrates 2DEG electron concentration calculation results for different Al compositions in each of the first barrier layer 104 and the second barrier layer 106 made of AlGaN, different thicknesses of each of the first barrier layer 104 and the second barrier layer 106, and different thicknesses of the second channel layer 105. The Al composition in each barrier layer varies in the order of 15%, 25%, and 35%, and the thickness of each barrier layer varies within a range of equal to or greater than 15 nm and equal to or less than 50 nm. As a result, it is found that, if the thickness of the second channel layer 105 is set at equal to or greater than 80 nm, the electron concentration in the 2DEG channel 113 is saturated.

Based on the foregoing measurement and calculation results, a multiple 2DEG channel structure in which the electron concentration in the 2DEG channel 113 formed in the second channel layer 105 is not reduced can be realized in such a manner that the thickness of the second channel layer 105 is set at equal to or greater than 80 nm.

### First Variation of First Embodiment

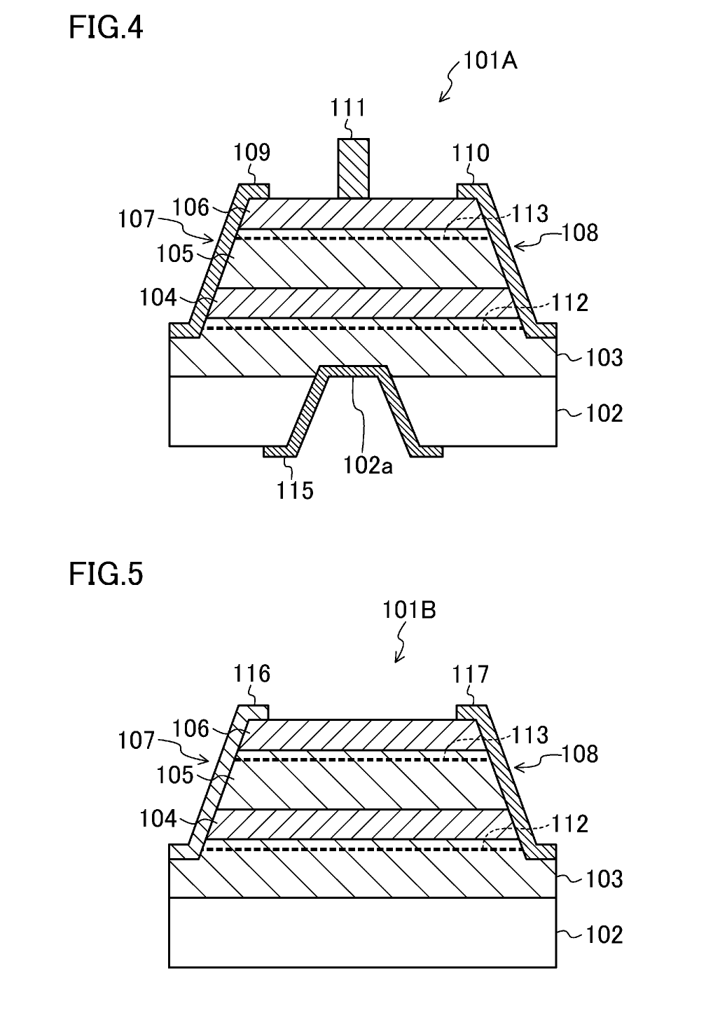

FIG. 4 illustrates a semiconductor device 101A of a first variation of the first embodiment.

The semiconductor device 101A illustrated in FIG. 4 is configured such that a second gate electrode 115 contacting a back surface of the first channel layer 103 is provided on a back side of the substrate 102 of the semiconductor device 101 of the first embodiment.

Specifically, a recess 102a through which the first channel layer 103 is exposed is formed in a region of the substrate 102 opposite to the gate electrode 111 (hereinafter referred to as a “first gate electrode 111” in the present variation). The second gate electrode 115 is, on the back side of the substrate 102, formed so as to extend along a wall surface of the recess 102a and to be in Schottky contact with part of the first channel layer 103 exposed at the bottom of the recess 102a.

As described above, since the gate electrode 111 and the second gate electrode facing the gate electrode 111 on a side close to the substrate 102 are used in combination with each other, current controllability for multiple 2DEG channels can be improved.

### Second Variation of First Embodiment

FIG. 5 illustrates a semiconductor device 101B of a second variation of the first embodiment.

Referring to FIG. 5, the semiconductor device 101B of the second variation is a Schottky barrier diode (SBD) including an anode electrode 116 in Schottky contact with the 2DEG channels 112, 113 and a cathode electrode 117 in ohmic contact with the 2DEG channels 112, 113.

Nickel (Ni) or palladium (Pd) may be used for the anode electrode 116. A multilayer film of titanium (Ti) and aluminum (Al) may be used for the cathode electrode 117.

In the SBD of the second variation, the thickness of the second channel layer 105 is preferably equal to or less than 350 nm, and more preferably equal to or less than 300 nm.

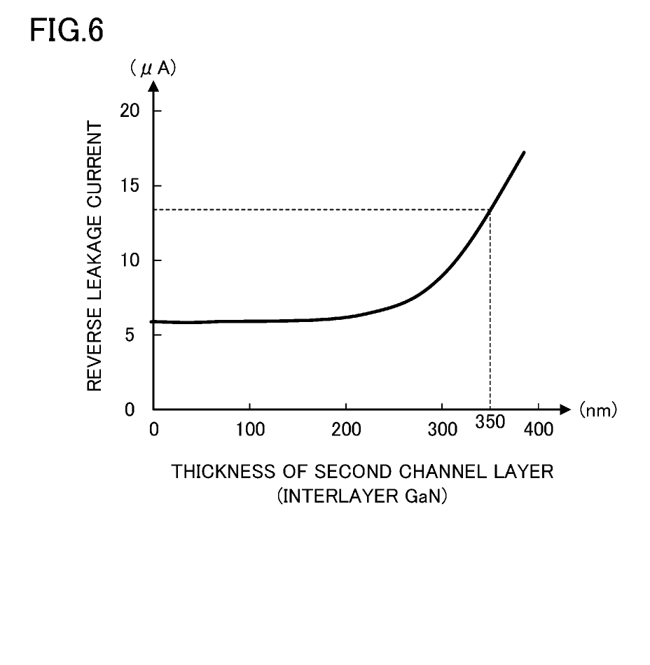

FIG. 6 illustrates measurement results of a relationship between the thickness of the second channel layer 105 and a reverse leakage current. FIG. 6 shows the following results. If the thickness of the second channel layer 105 is equal to or greater than 350 nm, the electron concentration in the 2DEG channel increases, but a Schottky barrier is reduced in reverse biasing. Thus, the reverse leakage current tunneling through the Schottky barrier increases.

In the first embodiment and the variations thereof, the multiple 2DEG channel structure is configured to have two channels, but may be configured to have three or more channels.

In the first embodiment and the variations thereof, the channel layers 103, 105 are made of GaN, and the barrier layers 104, 106 are made of AlGaN. However, as long as the semiconductor device is made of a group III nitride semiconductor and has such a composition that the band gap of the barrier layer 104, 106 is greater than that of the channel layer 103, 105, the present disclosure is not limited to the foregoing configuration.

### Third Variation of First Embodiment

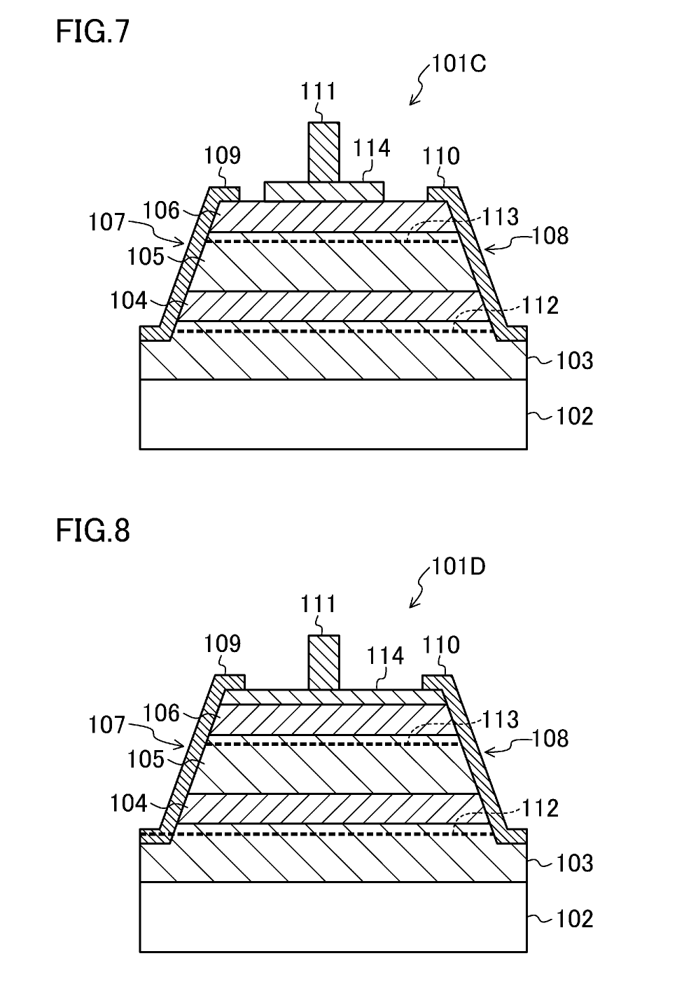

FIG. 7 illustrates a semiconductor device 101C of a third variation of the first embodiment.

The semiconductor device 101C of the third variation illustrated in FIG. 7 is configured such that an insulating film 114 is provided on the second barrier layer 106 of the semiconductor device 101 of the first embodiment and that the gate electrode 111 is formed on the insulating film 114. The insulating film 114 is selectively provided corresponding to the gate electrode 111 and the periphery thereof.

For example, a nitride film typified by silicon nitride (SiN) and aluminum nitride (AlN), an oxide film typified by aluminum oxide (AlO) and hafnium oxide (HfO), or a multilayer film thereof may be used as the insulating film 114. The insulating film 114 having a thickness of equal to or greater than 1 nm and equal to or less than 100 nm may be used. The typical thickness of the insulating film 114 is about 5 nm.

According to the foregoing configuration, advantages similar to those of the semiconductor device 101 of the first embodiment can be realized.

A semiconductor device 101D illustrated in FIG. 8 is, as another example, configured such that the insulating film 114 is not provided corresponding only to the gate electrode 111 and the periphery thereof, but is formed so as to reach the source electrode 109 and the drain electrode 110. Moreover, the source electrode 109 and the drain electrode 110 are formed so as to cover end parts of the insulating film 114. Even in such a configuration, advantages similar to those of the semiconductor device 101C of the third variation illustrated in FIG. 7 can be realized.

### Fourth Variation of First Embodiment

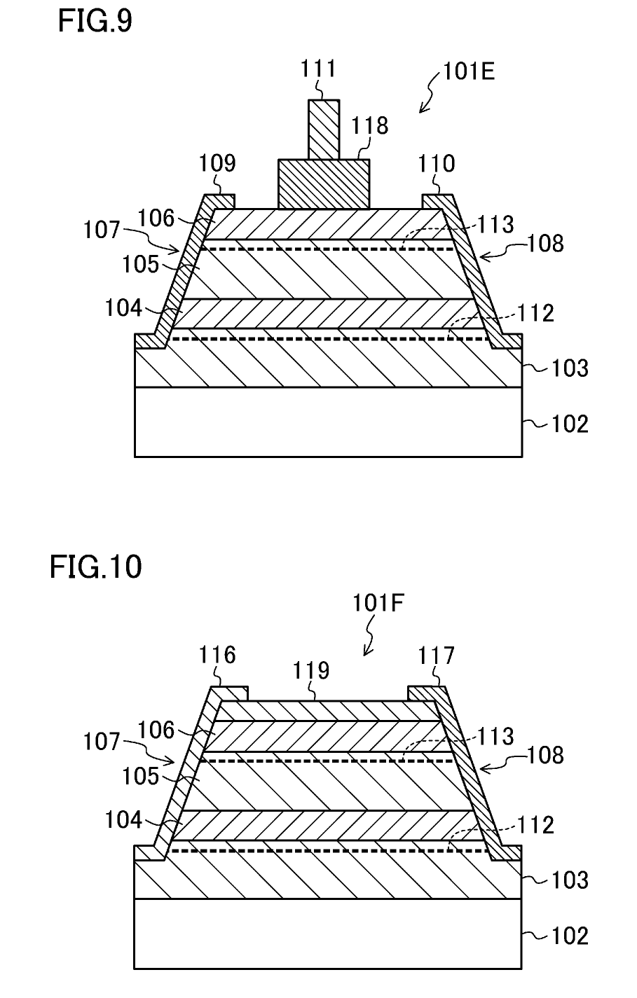

FIG. 9 illustrates a semiconductor device 101E of a fourth variation of the first embodiment.

The semiconductor device 101E of the fourth variation illustrated in FIG. 9 is configured such that a p-semiconductor layer 118 is provided on the second barrier layer 106 of the semiconductor device 101 of the first embodiment and that the gate electrode 111 is formed on the p-semiconductor layer 118. Note that the gate electrode 111 may exhibit ohmic characteristics with respect to the p-semiconductor layer 118.

For example, a Mg-doped GaN layer, a Mg-doped AlGaN layer, a Mg-doped AlInN layer, or a Mg-doped AlGaN layer is used as the p-semiconductor layer 118. The thickness of the p-semiconductor layer 118 is not limited, and the typical thickness of the p-semiconductor layer 118 is about 100 nm. Note that the p-semiconductor layer 118 may have a multilayer structure of two or more of a Mg-doped GaN layer(s) and a Mg-doped AlGaN layer(s). Moreover, e.g., an oxide semiconductor layer made of nickel oxide (NiO) may be used as the p-semiconductor layer 118.

According to the foregoing configuration, advantages similar to those of the semiconductor device of the first embodiment are realized.

### Fifth Variation of First Embodiment

FIG. 10 illustrates a semiconductor device 101F of a fifth variation of the first embodiment.

Referring to FIG. 10, the semiconductor device 101F of the fifth variation is a Schottky barrier diode (SBD) which includes the anode electrode 116 in Schottky contact with the 2DEG channels 112, 113 and the cathode electrode 117 in ohmic contact with the 2DEG channels 112, 113 and which is provided with an insulating film 119 formed on the second barrier layer 106.

For example, a nitride film typified by silicon nitride (SiN) and aluminum nitride (AlN), an oxide film typified by aluminum oxide (AlO) and hafnium oxide (HfO), or a multilayer film thereof may be used as the insulating film 119. The insulating film 119 having a thickness of equal to or greater than 1 nm and equal to or less than 100 nm may be used. The typical thickness of the insulating film 119 is about 5 nm.

According to the foregoing configuration, advantages similar to those of the semiconductor device of the second variation of the first embodiment are realized.

Nickel (Ni) or palladium (Pd) may be used for the anode electrode 116. A multilayer film of titanium (Ti) and aluminum (Al) may be used for the cathode electrode 117.

### Sixth Variation of First Embodiment

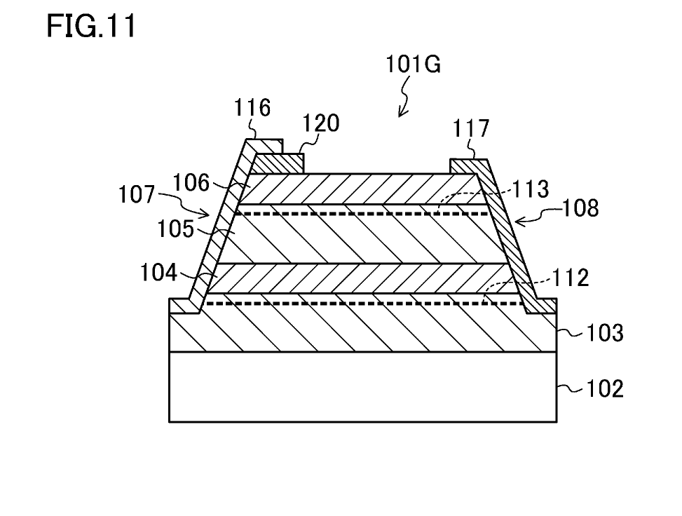

FIG. 11 illustrates a semiconductor device 101G of a sixth variation of the first embodiment.

Referring to FIG. 11, the semiconductor device 101G of the sixth variation is a Schottky barrier diode (SBD) which includes the anode electrode 116 in Schottky contact with the 2DEG channels 112, 113 and the cathode electrode 117 in ohmic contact with the 2DEG channels 112, 113. The SBD is further configured such that a p-semiconductor layer 120 is provided on part of the second barrier layer 106 close to the anode electrode 116 and that the anode electrode 116 is provided so as to cover part of the p-semiconductor layer 120.

For example, a Mg-doped GaN layer, a Mg-doped AlGaN layer, a Mg-doped AlInN layer, or a Mg-doped AlGaN layer is used as the p-semiconductor layer 120. The thickness of the p-semiconductor layer 120 is not limited, and the typical thickness of the p-semiconductor layer 120 is about 100 nm. Note that the p-semiconductor layer 120 may have a multilayer structure of two or more of a Mg-doped GaN layer(s) and a Mg-doped AlGaN layer(s).

According to the foregoing configuration, advantages similar to those of the semiconductor device of the second variation of the first embodiment are realized.

It is only necessary that the anode electrode 116 is in ohmic contact with the p-semiconductor layer 120, and, e.g., nickel (Ni) or palladium (Pd) may be used for the anode electrode 116. A multilayer film of titanium (Ti) and aluminum (Al) may be used for the cathode electrode 117.

### Second Embodiment

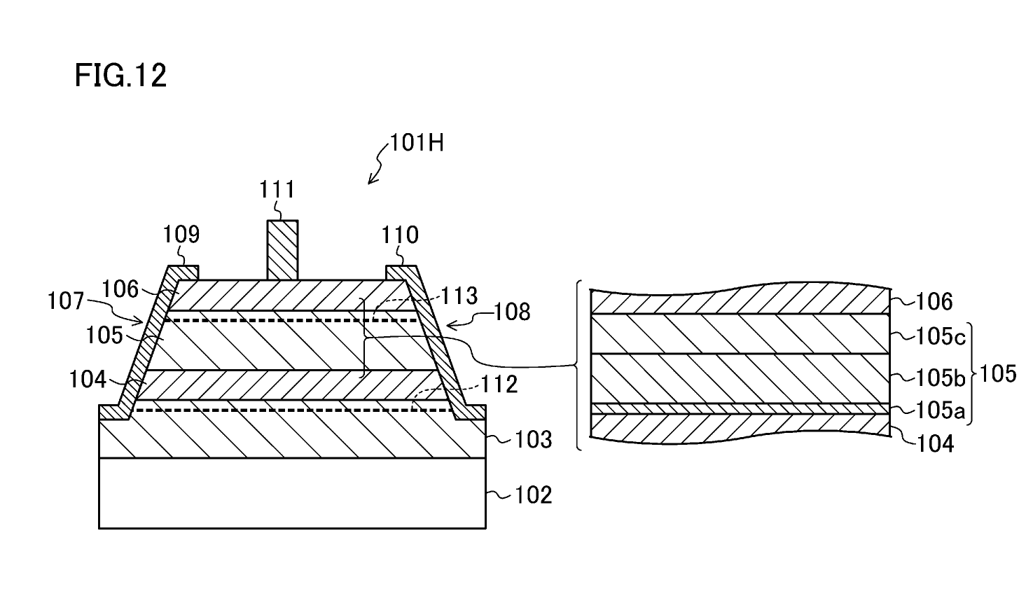

A semiconductor device of a second embodiment of the present disclosure will be described below with reference to FIG. 12.

Referring to FIG. 12, a semiconductor device 101H of the second embodiment is a GaN-based field effect transistor. The same reference numerals as those shown in the semiconductor device 101 of the first embodiment are used to represent equivalent elements of the semiconductor device 101H of the second embodiment.

A second channel layer 105 of the field effect transistor of the second embodiment is configured to have a plurality of regions (layers) with different conductivity types.

Specifically, in the second channel layer 105 made of GaN, a first region 105a contacting a first barrier layer 104 in which a negative polarization charge is generated is n-doped, and a second region 105b contacting part of the first region 105a opposite to the first barrier layer 104 is p-doped. An undoped third region 105c is interposed between the second region 105b and a second barrier layer 106.

An n-impurity concentration in the first region 105a is, e.g., 1×10¹⁹ cm ³, and the thickness of the first region 105a is, e.g., 10 nm. Moreover, a p-impurity concentration in the second region 105b is, e.g., 5×10¹⁷ cm³, and the thickness of the second region 105b is, e.g., 200 nm. Note that the impurity concentrations and the thicknesses of the regions 105a, 105b are not limited to the foregoing.

For the first region 105a, e.g., silicon (Si) may be used as an n-dopant. For the second region 105b, e.g., magnesium (Mg) may be used as a p-dopant.

According to the second embodiment, since the first region 105a doped with the n-impurity is formed so as to contact the first barrier layer 104, an electron concentration in a 2DEG channel 112 of a first channel layer 103 can be improved.

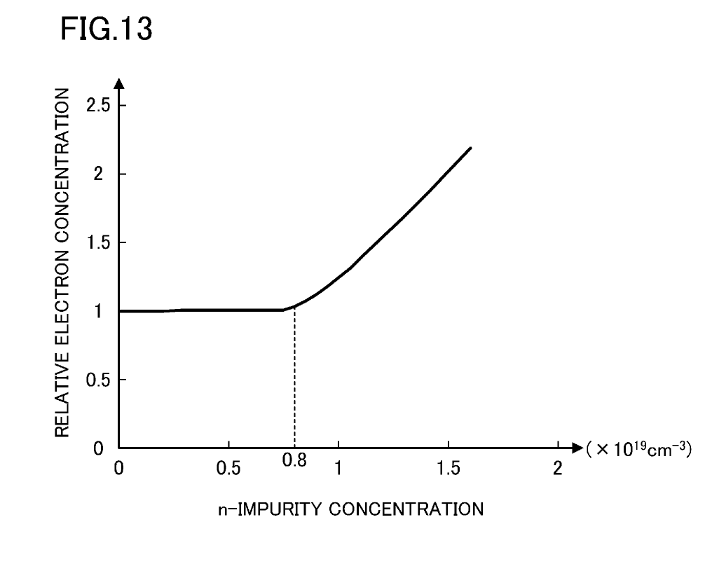

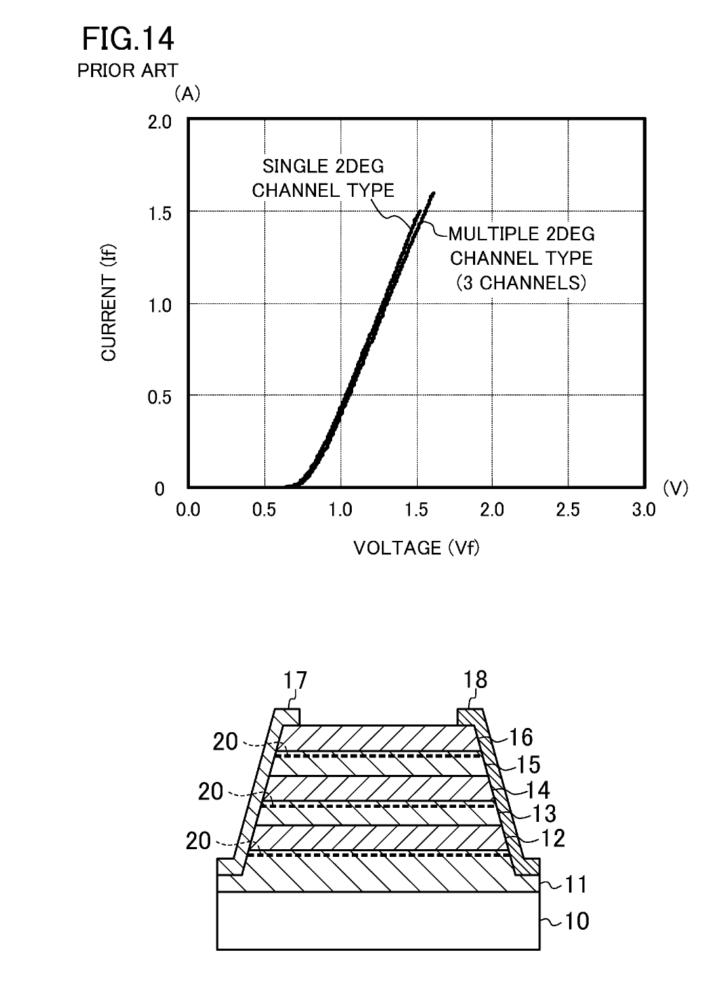

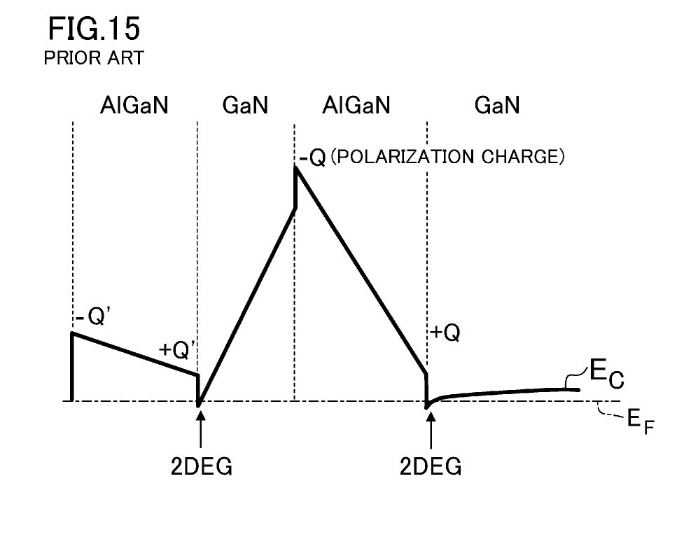

FIG. 13 illustrates calculation results of a relationship between the n-impurity concentration in the first region 105a and the electron concentration in the 2DEG channel 112 of the first channel layer 103. As will be seen from FIG. 13, the electron concentration in the 2DEG channel 112 of the first channel layer 103 is improved in such a manner that the n-impurity concentration in the first region 105a is set at equal to or greater than 8×10¹⁸ cm⁻³.

This is because the conductivity type of the first region 105a is the n-type, and therefore extension of a depletion layer toward the second channel layer 105 due to the negative polarization charge generated at an upper surface of the first barrier layer 104 can be reduced. Thus, an increase in potential of the first barrier layer 104 and the first channel layer 103 is reduced, and the electron concentration in the 2DEG channel 112 of the first channel layer 103 can be improved.

As described above, in the semiconductor device 101H of the second embodiment, the advantage that the electron concentration in the 2DEG channel 112 of the first channel layer 103 is improved can be realized in the case of a multiple 2DEG channel structure in which the second channel layer 105 is stacked on the first barrier layer 104.

It is preferred that the total amount (i.e., a value obtained by integrating the impurity concentration with the thickness) of n-impurity doped on the first region 105a and the total amount of p-impurity doped on the second region 105b are substantially equal to each other. Thus, if field intensity increases in a direction (i.e., a direction in which electrons flow) along the channel, the first region 105a and the second region 105b are depleted, and extension of such depletion layers reduces electric field concentration. Consequently, an improved high breakdown voltage of the semiconductor device 101H can be ensured.

In the light of operation characteristics of the semiconductor device 101H, if a higher priority is placed on a high current density rather than on the high breakdown voltage characteristics, the thickness of the p-type second region 105b may be reduced, or no p-type second region 105b may be provided. In such a case, the advantage that the electron concentration in the 2DEG channel 112 of the first channel layer 103 is improved can be realized.

As in the first embodiment, the thickness of the second channel layer 105 is preferably equal to or greater than 80 nm. However, depending on the impurity concentrations and thicknesses of the n-type first region 105a and the p-type second region 105b, the thickness of the second channel layer 105 is not limited to the foregoing.

As in the first variation of the first embodiment illustrated in FIG. 4, a recess 102a through which the first channel layer 103 is exposed may be, in the second embodiment, formed in a region of a back part of a substrate 102 opposite to a first gate electrode 111, and a second gate electrode 115 in Schottky contact with the bottom of the recess 102a may be formed.

Thus, the first gate electrode 111 and the second gate electrode 115 are combined together to control the semiconductor device 101H, and therefore current controllability for multiple 2DEG channels can be improved.

In the second embodiment, the field effect transistor has been described as the semiconductor device 101H. However, as in the second variation of the first embodiment illustrated in FIG. 5, the semiconductor device 101H may be a Schottky barrier diode (SBD) including a Schottky contact anode electrode 116 and an ohmic contact cathode electrode 117.

In the second embodiment and variations thereof, the multiple 2DEG channel structure is configured to have two channels, but may be configured to have three or more channels.

In the second embodiment and the variations thereof, the channel layers 103, 105 are made of GaN, and the barrier layers 104, 106 are made of AlGaN. However, as long as the semiconductor device is made of a group III nitride semiconductor and has such a composition that the band gap of the barrier layer 104, 106 is greater than that of the channel layer 103, 105, the present disclosure is not limited to the foregoing configuration.

The first and second embodiments may be combined together. For example, in the configuration in which a third hetero-junction body of a third channel layer and a third barrier layer is further provided on the second barrier layer 106, the second channel layer 105 may include the n-type first region 105a and the p-type second region 105b of the second embodiment, and the third channel layer may be configured as the undoped GaN layer of the first embodiment.

According to the present disclosure, in the semiconductor device made of the group III nitride semiconductor and having the multiple 2DEG channels, an effective increase in current density can be realized with size reduction and higher output power. The semiconductor device of the present disclosure is useful for, e.g., high-power semiconductor devices suitable for industrial power electronics equipment or power application circuits for electrical household appliances.

What is claimed is:

1. A semiconductor device comprising:
a first hetero-junction body in which a first nitride semiconductor layer and a second nitride semiconductor layer having a greater band gap than that of the first nitride semiconductor layer are bonded together;
a second hetero-junction body in which a third nitride semiconductor layer formed on the first hetero-junction body and a fourth nitride semiconductor layer having a greater band gap than that of the third nitride semiconductor layer are bonded together;
a first electrode in Schottky contact with at least the fourth nitride semiconductor layer; and
a second electrode in ohmic contact with the first and second hetero-junction bodies,
wherein the first nitride semiconductor layer has such a thickness that an electron concentration in a 2-dimentional electron gas layer formed in the first nitride semiconductor layer is not reduced, or
the third nitride semiconductor layer has such a thickness that an electron concentration in a 2-dimentional electron gas layer formed in the third nitride semiconductor layer is not reduced.

2. The semiconductor device of claim 1, wherein
the thickness of the first nitride semiconductor layer or the third nitride semiconductor layer is equal to or greater than 80 nm.

3. The semiconductor device of claim 1, wherein
the third nitride semiconductor layer has, at an interface at which the third nitride semiconductor layer contacts the second nitride semiconductor layer, a first region doped with an n-impurity.

4. The semiconductor device of claim 3, wherein
the third nitride semiconductor layer has a second region formed between the first region and the fourth nitride semiconductor layer so as to contact the first region and doped with a p-impurity.

5. The semiconductor device of claim 1, wherein
the first electrode is a gate electrode,
the second electrode includes a source electrode formed in a region extending over the first and second hetero-junction bodies on one side of the gate electrode, and a drain electrode formed in a region extending over the first and second hetero-junction bodies on the other side of the gate electrode, and
the semiconductor device is operated as a field effect transistor.

6. The semiconductor device of claim 5, wherein
the first electrode is a first gate electrode,
a substrate configured to hold the first hetero-junction body is further provided,
the substrate is provided in a region of the semiconductor device opposite to the first gate electrode, and is formed with an opening through which part of the first hetero-junction body is exposed, and
a second gate electrode contacting at least the part of the first hetero-junction body exposed through the opening is formed on the substrate.

7. The semiconductor device of claim 1, wherein
the first electrode is an anode electrode,
the second electrode is a cathode electrode, and
the semiconductor device is operated as a Schottky barrier diode.

8. The semiconductor device of claim 7, wherein
the thickness of the third nitride semiconductor layer is equal to or less than 350 nm.
